(19) United States
(12) Patent Application Publication
(10) Pub. No.: US 2025/0338571 A1
(43) Pub. Date: Oct. 30, 2025

(54) TRENCH GATE WIDE BANDGAP JUNCTION FIELD EFFECT TRANSISTORS WITH TERMINATION REGIONS HAVING PLANAR UPPER SURFACES

(71) Applicant: Wolfspeed, Inc., Durham, NC (US)

(72) Inventors: Madankumar Sampath, Durham, NC (US); Rahul Potera, Apex, NC (US); Sei-Hyung Ryu, Cary, NC (US); Steven Rogers, Stem, NC (US)

(21) Appl. No.: 18/646,862

(22) Filed: Apr. 26, 2024

(51) Int. Cl. H01L 29/06; H01L 29/78

(52) U.S. Cl. CPC H10D 62/107; H10D 30/615

(57) ABSTRACT

JFETs are provided that comprise a wide bandgap semiconductor layer structure comprising an active region and a termination region. The termination region comprises a plurality of termination structures. A first major surface of the semiconductor layer structure in the active region comprises a plurality of spaced-apart mesas and the first major surface of the semiconductor layer structure in the termination region is a planar surface.

### FIELD

The present invention relates to semiconductor devices and, more particularly, to junction field effect transistors, which are commonly referred to as “JFETs.”

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a substrate (e.g., a silicon carbide wafer) having a first conductivity type (e.g., an n-type substrate), on which a silicon carbide epitaxial layer structure is formed. Herein, the combination of any substrate (since the substrate may later be removed) and the epitaxial layers is referred to as a semiconductor layer structure. The semiconductor layer structure may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes an active region and an inactive region. The active region is the portion of the device that acts as a main junction for blocking voltage during off-state operation (also referred to as “reverse bias” or “reverse blocking” operation), and is also the portion of the device through which current flows during on-state operation (also referred to as “forward bias” operation). The inactive region may include, for example, a gate region and/or an edge termination region. The gate region may comprise some or all of the portion of the epitaxial layer structure that is underneath a gate pad of the device, as well as portions of the epitaxial layer structure that are underneath any gate buses. The edge termination region is a portion of the epitaxial layer structure that at least partially surrounds the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A power JFET is a three terminal device that has gate, drain and source terminals that are formed on a semiconductor layer structure. Source regions that are electrically connected to the source terminal and a drain region that is electrically connected to the drain terminal may be formed in the semiconductor layer structure. A plurality of channel regions are interposed in the semiconductor layer structure between the source regions and the drain region. The width, and hence the conductivity, of the channel regions may be controlled by an electric field where the electric field is controlled by a bias voltage that is applied between the gate and source terminals. Accordingly, a power JFET can be switched between its on and off states by applying appropriate voltages to the gate terminal thereof.

A gate structure of the power JFET may include, for example, a gate bond pad that serves as the gate terminal, an optional gate pad that is underneath and electrically connected to the gate bond pad, and one or more gate buses that distribute gate signals from the gate pad to gate electrodes that extend throughout the active region of the JFET. The gate bond pad, gate pad, gate buses and gate electrodes may comprise, for example, metal and/or silicide. The gate structure further includes gate regions and gate contact regions that are formed in the semiconductor layer structure of the device. The gate regions and gate contact regions may have a conductivity type opposite the conductivity type of the channel regions, with the gate contact regions having higher doping concentrations than the gate regions. The gate electrodes are connected to the gate regions through the gate contact regions. In many cases, power JFETs may have a trench gate design where the active region of the semiconductor layer structure includes a plurality of mesas and trenches that are defined in between adjacent mesas. Trench gate JFETs may be preferred because carrier mobility in the channel regions of these devices may be significantly greater than the channel mobility in JFETs having planar gate regions. In a trench gate power JFET, the gate electrodes are formed in the respective trenches, and the gate contact regions are formed in the semiconductor layer structure underneath the respective trenches. The gate regions are formed on sidewalls of the gate contact regions and may also extend upwardly so that the gate regions form the lower portions of the sidewalls of the trenches. The gate regions are disposed adjacent the respective channel regions so that application of a gate bias voltage at the gate terminal controls the electric fields in the channel regions.

Power JFETs are typically normally-on devices, meaning that a JFET conducts current when a voltage of 0 volts is applied to the gate structure. In order to convert a silicon carbide-based power JFET from a normally-on device to a normally-off device, a low-power MOSFET (which is typically an inexpensive silicon-based MOSFET) may be coupled to the power JFET in a cascode configuration to form an integrated normally-off JFET switch. FIG. 1 is a circuit diagram of such an integrated normally-off JFET switch 1 that includes a high-power JFET 10 cascoded with a low-power normally-off MOSFET 30. As shown in FIG. 1, the gate terminal G_{MOS} of the MOSFET 30 acts as the gate terminal G_{SW} of the switch 1, the source terminal S_{MOS} of the MOSFET 30 acts as the source terminal S_{SW} of the switch 1, and the drain terminal D_{JFET} of the JFET 10 acts as the drain terminal D_{SW} of the switch 1. The source terminal S_{JFET} of the JFET 10 is coupled to the drain terminal D_{MOS} of the MOSFET 30, and the gate terminal G_{JFET} of the JFET 10 is coupled to the source terminal S_{MOS} of the MOSFET 30. When the MOSFET 30 is turned off, the drain terminal D_{MOS} of the MOSFET 30, and hence the source terminal S_{JFET} of the JFET 10, may be at a large positive voltage, which would mean that the gate terminal G_{JFET} of the JFET relative to the source terminal S_{JFET} of the JFET may be at a large negative voltage (e.g., −30 volts). This large negative voltage acts to keep the JFET 10 from conducting. When the MOSFET 30 is turned on, the drain terminal D_{MOS} of the MOSFET 30, and hence the source terminal S_{JFET} of the JFET 10, may be at a voltage of near zero, allowing the JFET 10 to turn on. Thus, the integrated normally-off JFET switch 1 of FIG. 1 will operate as a normally-off device that turns on by applying a voltage to the gate terminal G_{MOS} of the MOSFET 30 that exceeds a threshold voltage of the MOSFET 30.

### SUMMARY

Pursuant to some embodiments of the present invention, JFETs are provided that comprise a wide bandgap semiconductor layer structure comprising an active region and a termination region. The termination region comprises a plurality of termination structures. A first major surface of the semiconductor layer structure in the active region comprises a plurality of spaced-apart mesas and the first major surface of the semiconductor layer structure in the termination region is a planar surface.

In some embodiments, the semiconductor layer structure further comprises a plurality trenches in the active region. In some embodiments, each trench is a longitudinally-extending trench that is defined between a respective pair of adjacent mesas.

In some embodiments, the first major surface of the semiconductor layer structure in the termination region is coplanar with upper surfaces of the mesas. In other embodiments, the first major surface of the semiconductor layer structure in the termination region is substantially coplanar with bottom surfaces of the trenches. In still other embodiments, the first major surface of the semiconductor layer structure in the termination region is closer to a second major surface of the semiconductor layer structure that is opposite the first major surface of the semiconductor layer structure than are upper surfaces of the mesas. In some embodiments, the first major surface of the semiconductor layer structure in the termination region is further from the second major surface of the semiconductor layer structure than are bottom surfaces of the trenches.

In some embodiments, in the active region, the semiconductor layer structure further comprises a drift region having a first conductivity type, a channel region having the first conductivity type, and a plurality of gate regions having a second conductivity type.

In some embodiments, the gate regions are formed in the lower portions of sidewalls of the trenches. In some embodiments, in the active region, the semiconductor layer structure further comprises a plurality of gate contact regions having the second conductivity type that are located underneath the respective trenches, wherein the gate contact regions have a higher second conductivity type dopant concentration than the gate regions. In some embodiments, the gate regions at least partially cover sidewalls of the gate contact regions.

In some embodiments, the plurality of termination structures comprises a plurality of guard rings that have the second conductivity type, and at least one of the guard rings extends to the first major surface of the semiconductor layer structure in the termination region. In some embodiments, each guard ring comprises a central region and first and second outer regions that at least partially cover sidewalls of the central region, where the central region has a higher second conductivity type dopant concentration than the first and second outer regions. In some embodiments, a first height of the gate regions in a depth direction that is perpendicular to a second major surface of the semiconductor layer structure that is opposite the first major surface of the semiconductor layer structure is greater than a second height of the outer regions of the guard rings in the depth direction. In some embodiments, the JFET further comprises a gate pad, and the semiconductor layer structure further comprises a gate well region having a second conductivity type region underneath the gate pad, wherein bottom surfaces of central regions of the guard rings are coplanar with the bottom surface of the gate well region.

In some embodiments, the JFET further comprises a gate pad, and the semiconductor layer structure further comprises a gate well region having a second conductivity type region underneath the gate pad, where a bottom surface of the gate well region is coplanar with a bottom surface of at least a portion of each termination structure. In some embodiments, the entirety of the bottom surface of each termination structure is coplanar with the bottom surface of the gate well region.

Pursuant to some embodiments of the present invention, JFETs are provided that comprise a wide bandgap semiconductor layer structure that comprises an active region and a termination region, where a plurality of trenches are provided in an upper surface of the semiconductor layer structure in the active region. The semiconductor layer structure comprises a drift region having a first conductivity type and a plurality of gate contact regions having a second conductivity type that are located underneath the respective trenches in the active region, and first and second guard rings having the second conductivity type in the termination region. Upper surfaces of the first and second guard rings are coplanar with an upper surface of a portion of the semiconductor layer structure that is in between the first and second guard rings.

In some embodiments, upper surfaces of the first and second guard rings form part of the upper surface of the semiconductor layer structure in the termination region.

In some embodiments, the gate contact regions have a higher second conductivity type dopant concentration than the first and second guard rings.

In some embodiments, the semiconductor layer structure further comprises a plurality of gate regions having the second conductivity type, where at least some of the gate regions at least partially cover respective sidewalls of the gate contact regions, wherein the gate contact regions have a higher second conductivity type dopant concentration than the gate regions.

In some embodiments, in the active region, the semiconductor layer structure comprises a plurality of source mesas, and the trenches are defined between adjacent pairs of source mesas. In some embodiments, the upper surfaces of the first and second guard rings are coplanar with upper surfaces of the source mesas.

In some embodiments, the upper surfaces of the first and second guard rings are substantially coplanar with bottom surfaces of the trenches.

In some embodiments, upper surfaces of the first and second guard rings are closer to a lower surface of the semiconductor layer structure than are upper surfaces of the source mesas and is further from the lower surface of the semiconductor layer structure than are bottom surfaces of the trenches.

In some embodiments, the first guard ring comprises a central region and first and second outer regions that at least partially cover sidewalls of the central region, where the central region has a higher second conductivity type dopant concentration than the first and second outer regions.

In some embodiments, a first height of the gate regions in a depth direction that is perpendicular to a lower surface of the semiconductor layer structure is greater than second heights of the first and second outer regions of the first guard ring in the depth direction.

In some embodiments, the JFET further comprises a gate pad, and the semiconductor layer structure further comprises a gate well region having a second conductivity type region underneath the gate pad, wherein a bottom surface of the central region of the first guard ring is coplanar with the bottom surface of the gate well region.

Pursuant to additional embodiments of the present invention, JFETs are provided that comprise an active region and a termination region that at least partially surrounds the active region. These JFETs comprise a semiconductor layer structure that comprises a wide bandgap semiconductor material, the semiconductor layer structure comprising a drift region having a first conductivity type, a plurality of source mesas on the drift region in the active region, and a plurality of trenches that are defined between respective adjacent pairs of the source mesas. The semiconductor layer structure has a planar upper surface in the termination region that is not coplanar with a plane defined by upper surfaces of the source mesas.

In some embodiments, the planar upper surface of the semiconductor layer structure in the termination region is recessed below upper surfaces of the source mesas. In some embodiments, the planar upper surface of the semiconductor layer structure in the termination region is substantially coplanar with bottom surfaces of the trenches. In some embodiments, the planar upper surface of the semiconductor layer structure in the termination region is closer to a lower surface of the semiconductor layer structure than are upper surfaces of the source mesas and is further from the lower surface of the semiconductor layer structure than are bottom surfaces of the trenches.

In some embodiments, the semiconductor layer structure further comprises a plurality of gate regions having a second conductivity type that are formed in lower portions of sidewalls of the trenches. In some embodiments, the semiconductor layer structure further comprises a plurality of gate contact regions having the second conductivity type that are located underneath the respective trenches, wherein the gate contact regions have a higher second conductivity type dopant concentration than do the gate regions, and the gate regions at least partially cover sidewalls of the gate contact regions.

In some embodiments, the termination region comprises a plurality of guard rings that have the second conductivity type, and at least one of the guard rings extends to the planar upper surface of the semiconductor layer structure in the termination region. In some embodiments, each guard ring comprises a central region and first and second outer regions that at least partially cover sidewalls of the central region, where the central region has a higher second conductivity type dopant concentration than the first and second outer regions.

In some embodiments, a first height of the gate regions in a depth direction that is perpendicular to a lower surface of the semiconductor layer structure is greater than second heights of the first and second outer regions of the guard rings in the depth direction.

In some embodiments, the JFET further comprises a gate pad, and the semiconductor layer structure further comprises a gate well region having a second conductivity type region underneath the gate pad, wherein bottom surfaces of the central regions of the guard rings are coplanar with the bottom surface of the gate well region.

In some embodiments, the JFET further comprises a gate pad, and the semiconductor layer structure further comprises a gate well region having a second conductivity type region underneath the gate pad and a plurality of termination structures in the termination region, where a bottom surface of the gate well region is coplanar with bottom surfaces of at least a portion of each termination structure.

In some embodiments, the entirety of the bottom surface of each termination structure is coplanar with the bottom surface of the gate well region.

Pursuant to yet additional embodiments of the present invention, JFETs are provided that comprise a semiconductor layer structure that comprises a drift region having a first conductivity type, the drift region comprising a wide bandgap semiconductor material. The semiconductor layer structure comprises an active region having a plurality of source mesas and a plurality of trenches that are defined between respective adjacent pairs of the source mesas and a termination region that comprises a plurality of guard rings that have a second conductivity type, wherein each guard ring has a planar upper surface and outer portions of each guard ring and a central portion of each guard ring have a same doping concentration as a function of depth into the semiconductor layer structure.

In some embodiments, the termination region has a planar upper surface. In some embodiments, an upper surface of the semiconductor layer structure in the termination region is coplanar with a plane defined by upper surfaces of the source mesas. In some embodiments, an upper surface of the semiconductor layer structure in the termination region is coplanar with a plane defined by bottom surfaces of the trenches. In some embodiments, an upper surface of the semiconductor layer structure in the termination region defines a plane that is in between a plane defined by upper surfaces of the source mesas and a plane defined by bottom surfaces of the trenches.

In some embodiments, the guard rings form part of an upper surface of the semiconductor layer structure in the termination region.

Pursuant to still further embodiments of the invention, methods of fabricating JFETs are provided in which a wide bandgap semiconductor layer structure is provided that comprises a drift region having a first conductivity type, a channel region having the first conductivity type on the drift region, and a source region having the first conductivity type on the channel region so that the channel region is between the drift region and the source region. A first etch mask layer is formed on a first major surface of the semiconductor layer structure. The first etch mask layer is patterned to form a first etch mask that exposes selected portions of a first region of the semiconductor layer structure while covering a second region of the semiconductor layer structure, the second region at least partially surrounding the first region. A plurality of trenches are etched in the first region using the first etch mask as an etching mask.

In some embodiments, the first region comprises an active region of the JFET and the second region comprises a termination region of the JFET.

In some embodiments, the method further comprises forming a second etch mask layer on the first major surface of the semiconductor layer structure, patterning the second etch mask layer to form a second etch mask that exposes at least portion portions of the second region of the semiconductor layer structure while covering the first region of the semiconductor layer structure, and etching the second region using the second etch mask as an etching mask.

In some embodiments, the termination region of the JFET has a planar upper surface after the second region is etched using the second etch mask as an etching mask.

In some embodiments, the method further comprises selectively implanting second conductivity type dopant ions into a gate region portion of the first region and into the second region to form a gate well region in the first region and a plurality of guard rings in the second region.

In some embodiments, each trench is defined in between a respective pair of source mesas.

In some embodiments, upper surfaces of the guard rings are coplanar with a plane defined by upper surfaces of the source mesas.

In some embodiments, the termination region has a planar upper surface that is not coplanar with upper surfaces of the source mesas.

In some embodiments, the termination region has a planar upper surface.

Pursuant to still further embodiments of the invention, methods of fabricating JFETs are provided in which a wide bandgap semiconductor layer structure is provided that comprises a drift region having a first conductivity type, a channel region having the first conductivity type on the drift region, and a source region having the first conductivity type on the channel region so that the channel region is between the drift region and the source region. An etching process is performed to form a recess in a first major surface of the semiconductor layer structure throughout an entirety of a termination region of the JFET, where the termination region at least partially surrounds an active region of the JFET.

In some embodiments, during the etching process a plurality of trenches are formed in the first major surface of the semiconductor layer structure in the active region.

In some embodiments, after performing the etching process an upper surface of the termination region is substantially coplanar with a plane defined by the bottoms of the trenches in the active region.

In some embodiments, the method further comprises selectively implanting second conductivity dopant ions in both the active region and the termination region to form a plurality of gate contact regions underneath the respective trenches in the active region and to form at least respective portions of a plurality of guard rings in the termination region.

In some embodiments, performing the etching process to form the recess in the first major surface of the semiconductor layer structure throughout the entirety of the termination region of the JFET comprises forming a first etch mask layer on the first major surface of the semiconductor layer structure, patterning the first etch mask layer to form a first etch mask that exposes the termination region of the semiconductor layer structure as well as selected portions of an active region and a gate region of the semiconductor layer structure, and etching the plurality of trenches in the active region selectively etching the gate region and etching termination region using the first etch mask as an etching mask.

In some embodiments, the method further comprises forming a second mask that covers selective portions of the termination region and simultaneously implanting second conductivity dopant ions in the active region using the first mask as an ion implantation mask and implanting second conductivity dopant ions in the termination region using the second mask as an ion implantation mask to form a plurality of gate contact regions underneath the respective trenches in the active region and to form respective portions of a plurality of guard rings in the termination region.

In some embodiments, the method further comprises performing one or more angled ion implants using the first and second masks as ion implantation masks to form a plurality of gate regions in the active region and to form the remainder of the guard rings in the termination region.

### BRIEF DESCRIPTION OF DRAWINGS

FIG. 1 is a circuit diagram of an integrated normally-off JFET switch that comprises a high-power JFET and a low-power MOSFET in cascode configuration.

FIG. 2A is a schematic plan view of a conventional power JFET.

FIGS. 2B and 2C are schematic cross-sectional diagrams taken along lines B-B and C-C of FIG. 2A, respectively.

FIGS. 3A and 3B are a schematic plan view and cross-sectional view, respectively, of a silicon carbide based gate trench power JFET according to embodiments of the present invention.

FIGS. 4A and 4B are a schematic plan view and cross-sectional view, respectively, of a silicon carbide based gate trench power JFET according to further embodiments of the present invention.

FIG. 5 is a schematic cross-sectional view of a power JFET according to still further embodiments of the present invention.

FIGS. 6A-6C are schematic cross-sectional views illustrating a method of fabricating the power JFET of FIG. 5.

### DETAILED DESCRIPTION

Power JFETs may be desirable for certain applications because they have high current carrying capability, high reliability, and may be formed using a simpler process than a comparably-rated power MOSFET. Moreover, as discussed above, a power JFET can be converted from a normally-on device to a normally-off device by connecting an inexpensive, low-voltage MOSFET in cascode configuration to the power JFET to provide an integrated normally-off JFET switch.

As discussed above, a trench gate power JFET includes a plurality of trenches that extend throughout the active region of the device. A plurality of mesas that are typically referred to as “source mesas” are defined between adjacent trenches. The trenches typically extend in parallel to each other so that each source mesa has a fin shape with the longitudinal axes of the source mesas extending in parallel to the longitudinal axes of the trenches. The source regions of the JFET, which are semiconductor regions having the same conductivity type as the channel regions and a higher doping concentration, are formed in the upper portion of each fin-shaped mesa, which is why the fins are referred to as source mesas. As discussed above, gate contact regions and gate regions that have conductivity types that are opposite the conductivity type of the channel regions are formed underneath the trenches and beside the lower portions of the trenches, respectively.

As is also discussed above, power semiconductor devices typically include edge termination regions that include one or more termination structures such as guard rings. In gate trench power JFETs, the guard rings have a conductivity type opposite the conductivity type of the channel regions, and hence the guard rings have the same conductivity type as the gate regions and the gate contact regions. The guard rings are typically formed using the same etching and ion implantation processes that are used to form the trenches, gate regions and gate contact regions. Since the guard rings are formed using the same processes that are used to form the gate regions and gate contact regions, a plurality of ring shaped trenches are formed in the termination region and the guard rings are formed underneath the respective trenches and in the sidewalls of the trenches. The ion implantation processes that are used to form the gate regions and the gate contact regions are also performed in the termination region and hence each guard ring may (in cross-section) look identical to the gate regions and gate contact regions that are formed in the active region.

Formation of the trenches, gate regions and the gate contact regions in the active region and the corresponding trenches and guard rings in the termination region requires a number of processing steps. For example, a first mask layer may be formed and then patterned using photolithography to form a first mask that is used when the semiconductor layer structure is etched to form the trenches and source mesas. A first ion implantation process may then be performed to form the gate contact regions (and the corresponding portions of the guard rings) and additional angled ion implantation processes are performed to form the gate regions and the remainder of the guard rings. The first etch mask may then be removed. Next, a second mask layer may be formed and then patterned using photolithography to form a second mask. The second mask may cover the termination region while exposing the active region of the device. A spacer insulation layer may then be formed on the upper surface of the semiconductor layer structure in the active region and on the second mask in the termination region. A third mask layer may then be formed and patterned using lithography to form a third mask and a second etching step may then be performed using the third mask to etch away most of the spacer layer in the active region so that the spacer layer only remains on the sidewalls of the trenches in the active region (thereby exposing the source mesas and central portions of the gate contact regions). Metal may then be deposited in the active region on the source regions and on the gate contact regions, and an annealing step may be performed to convert the metal into silicide, thereby forming silicide gate electrodes in the trenches on the gate contact regions and silicide ohmic contacts on the source regions. Finally, the trenches in both the active region and the termination region may be filled with a dielectric layer.

The present invention is based, at least in part, on a realization that there are several difficulties with the above-described process that is used to form the guard rings in conventional gate trench power JFETs.

First, most processing steps have associated tolerances, and the more processing steps that are performed, the more these tolerances combine to create a greater degree of uncertainty regarding where certain regions (e.g., the guard rings) are formed in a device. the sizes and doping concentrations of the regions, etc. Since the same processing steps are used to form both the gate structures in the active region and the guard rings in the termination region, a relatively large number of different masking, etching and implanting steps are used to form the guard rings. As the tolerances associated with each processing step are additive, the above technique results in greater variation in the actual locations and shapes of the guard rings in manufactured devices, and in their doping profiles. Ideally, the locations, shapes and doping concentrations of the guard rings are carefully controlled so that the guard rings shape the electric fields in the termination region in a desired fashion to reduce the risk of avalanche breakdown during device operation. The larger combined tolerances that results from forming the guard rings using the same processing steps that are used to form the gate structures in the active regions increases the variability in the locations, shapes and doping concentrations of the guard rings in manufactured devices, which may negatively impact the electric field shaping in the termination region and hence make the JFET more susceptible to premature avalanche breakdown.

Second, since the guard rings are formed using the same ion implantation processes that are used to form the gate regions and the gate contact regions, it is not possible to separately optimize the doping concentrations, implant depths and shapes of the gate regions/gate contact regions versus the guard rings. The shapes and doping concentrations of the gate regions and gate contact regions may not be ideal for optimally shaping the electric fields in the termination region during reverse bias operation. Again, this can make the JFET more susceptible to premature avalanche breakdown.

Third, gate trench JFETs include p-n junctions in the sidewalls of the trenches in the active region. When the guard rings are formed using the same process steps as the gate regions/gate contact regions in the active region, the guard rings likewise include such p-n junctions in the sidewalls of the trenches in the termination region. Unfortunately, these p-n junctions can lead to premature gate-drain leakage. The likelihood of such premature gate-drain leakage may be reduced or eliminated by adjusting the profile of the mesas or by performing surface treatments on the sidewalls of the trenches. However, such changes to the mesa profiles and/or the surface treatment can negatively affect the on-state performance of the JFET.

Pursuant to embodiments of the present invention, gate trench JFETs are provided that include termination regions that have planar upper surfaces. Since the termination region does not have an alternating mesa/trench design, the etch profile that is used to form the trenches in the active region may be optimized based on the on-state requirements of the JFET, without having to consider the performance of the termination region. In addition, since trenches are not formed in the termination region, the tolerances associated with the trench etching steps (e.g., masking tolerance, etching tolerances, etc.) are eliminated, allowing the guard rings (or other termination structures) to be more precisely located in production devices. This may further improve the performance of the termination structures. Also, since trenches are not formed in the termination region, the above-discussed risk of premature gate-drain leakage may be avoided since there are no p-n junctions in trench sidewalls in the termination region. Moreover, the shape and doping profile of the guard rings may be selected to optimize the electric field distribution in the termination region without having to consider how the doping profile impacts on-state performance (since the gate regions and gate contact regions are formed separately from the guard rings).

In some embodiments, the JFETs disclosed herein may have termination regions that have upper surfaces that are coplanar with the upper surfaces of the source mesas in the active region of the device. In such embodiments, the guard rings may be formed, for example, using a single ion implantation process that is optimized for performance of the guard rings. This ion implantation may be performed, for example, before the trench etch in the active region, and may also be used to form the implanted region under the gate pad.

In other embodiments, the etching step that is used to form the trenches in the active region may also be used to etch the termination region, but the entirety of the termination region may be etched so that the termination region still has a planar upper surface. In such embodiments, the guard rings may be formed using the same ion implantation steps that are used to form the gate regions and the gate contact regions in the active region of the device, thereby avoiding any need for an extra ion implantation step. An extra ion implantation mask may be formed in the termination region before these ion implantation processes. This extra ion implantation mask is used to “simulate” source mesas in the termination region.

In still further embodiments, the JFETs may have termination regions that have upper surfaces that are recessed below the upper surfaces of the source mesas in the active region of the device, but that are not recessed as deeply as the bottom surfaces of the trenches. In such embodiments, the guard rings may be formed, for example, using a single ion implantation process that is optimized for performance of the guard rings. Since the upper surface of the termination region is recessed to an extent, a somewhat lower energy ion implantation process may be used to form the guard rings.

Before describing various gate trench power JFETs according to embodiments of the present invention, it is helpful to describe a conventional silicon carbide based gate trench power JFET 100.

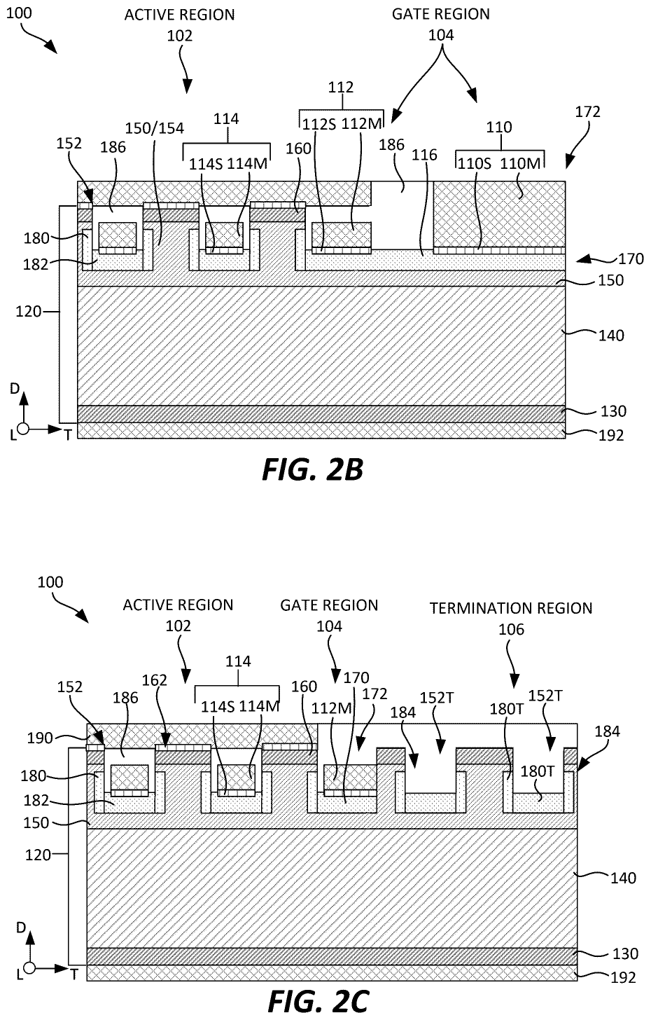

FIG. 2A is a schematic plan view of the conventional gate trench power JFET 100. In FIG. 2A, several of the upper layers of the JFET 100 including the source and gate bond pads, the source contact, the gate insulating patterns and the upper passivation/protection patterns are omitted to better show the underlying regions of the power JFET 100. FIGS. 2B-2C are schematic cross-sectional diagrams taken along lines B-B and C-C of FIG. 2A, respectively. To provide additional context, the source contact 190 and the gate insulating patterns 186 that are omitted in FIG. 2A are shown in FIGS. 2B and 2C, although the other layers discussed above are still omitted in FIGS. 2B-2C.

Referring first to FIG. 2A, the power JFET 100 includes an active region 102, a gate pad/bus region 104, and a termination region 106 that surrounds the active region 102 when the JFET 100 is viewed in plan view.

As discussed above, the active region 102 is the portion of the power JFET 100 that acts as a main junction for blocking voltage during off-state operation and current flows through the active region 102 during on-state operation. The power JFET 100 may have a unit cell structure such that a large number of individual “unit cell” JFETs are formed in the active region 102 and electrically connected in parallel to each other so that the unit cells together function as a single power JFET 100. Each unit cell includes a gate electrode 114. In the depicted embodiment, each gate electrode 114 has a longitudinal axis that extends in the longitudinal direction L in the view of FIG. 2A, and the gate electrodes 114 are spaced apart from one another in the transverse direction T (the transverse direction T and the depth direction D are also shown in FIG. 2A). Each gate electrode 114 is formed within a respective trench 152 (see FIGS. 2B-2C) that is formed in the upper surface of the semiconductor layer structure of JFET 100.

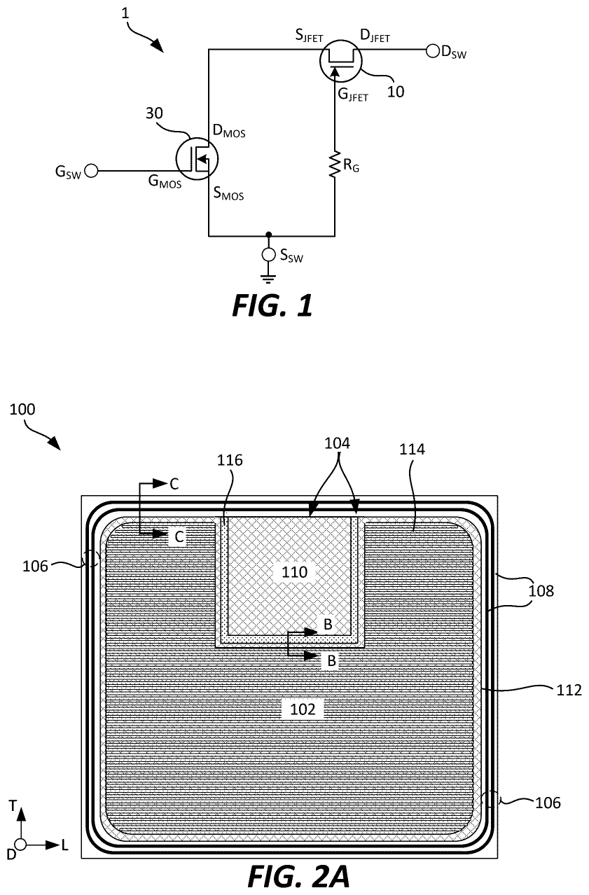

The gate region 104 is the region corresponding to a gate pad 110, a gate bus 112 and a gate resistor 116. The gate pad 110 may comprise a metal pad and may be provided underneath a metal gate bond pad (not shown) if a separate metal gate bond pad is provided. The gate bond pad (or the gate pad 110 if no separate gate bond pad is provided) may be connected to an external circuit (e.g., to a MOSFET of an integrated normally-off JFET switch) through bond wires, leads or other electrical connections. The gate pad 110 and the gate bus 112 may each include a metal portion and a metal silicide portion. The gate pad 110 is physically and electrically connected to the gate bus 112 through the gate resistor 116. The gate resistor 116 may comprise a region (typically a p-type region) in the silicon carbide based semiconductor layer structure of JFET 100 (see FIGS. 2B-2C) and is interposed between the gate pad 110 and the gate bus 112 such that gate signals must flow through the gate resistor 116 to pass from the gate pad 110 to the gate bus 112. Since the resistivity of p-type silicon carbide is many orders of magnitude greater than the resistance of a silicide or metal (e.g., about five orders of magnitude greater than a silicide), the p-type silicon carbide region effectively forms a lumped gate resistor. The gate resistor 116 generally corresponds to gate resistor RG in FIG. 1, but is interposed on the electrical path between the gate pad 110 and the gate bus 112 as opposed to being a resistor that is external to JFET 100. The gate bus 112 may be a high conductivity bus that carries gate signals received from the gate pad 110 to the gate electrodes 114 that are provided in the active region 102. It will be appreciated that the gate resistor 116 may be omitted in some embodiments, and that any appropriate design for the gate bus 112 may be used. For example, in another example embodiment the gate resistor 116 is omitted and the gate bus does not extend around the gate pad 110 and/or does not extend around the bottom of the active region 102. It will also be appreciated that some of the gate electrodes 114 may directly connect to the gate pad 110 rather than connecting to the gate pad 110 through the gate bus and/or the gate resistor 116.

The edge termination region 106 is a region that at least partially surrounds the active region 102 and the gate region 104. The edge termination region 106 is designed to spread the electric fields that extend throughout the semiconductor layer structure 120 during reverse blocking operation out over a greater area in order to reduce electric field crowding effects that would otherwise occur along the outer edges of the active region 102. The termination region 106 comprises one or more termination structures 108 such as guard rings, a junction termination extension or the like. In FIG. 2A, the termination structures are schematically shown as being two guard rings 108, which are p-type regions that are formed as rings around the active region 102 that surround the active region 102 and the gate region 104 when the JFET 100 is viewed in plan view (i.e., from above). The number and type of termination structures included in the termination region 106 may be changed from that which is shown in FIG. 2A.

FIG. 2B is a schematic cross-sectional view taken along line B-B of FIG. 2A. The cross-section of FIG. 2B helps illustrate how gate signals that are applied to the gate pad 110 are distributed throughout the active region 102 of JFET 100. FIG. 2B also schematically illustrates the various elements and regions formed in the semiconductor layer structure 120 of JFET 100. The cross-section of FIG. 2B illustrates the device design in the region where the gate pad 110 borders the active region 102.

Referring to FIG. 2B, the semiconductor layer structure 120 may include a substrate 130, a drift region 140, channel regions 150, source regions 160, a gate well region 170 that includes the gate resistor 116, gate regions 180 and gate contact regions 182.

The substrate 130 may be formed of wide bandgap semiconductor materials (e.g., may be a silicon carbide substrate) and may be heavily doped with n-type (n+) dopants in example embodiments. The substrate 130 may have a doping concentration of 1×10¹⁸ to 1×10²¹ dopants/cm³ in example embodiments. The substrate 130 may be omitted (e.g., removed after epitaxial growth) in some cases. The substrate 130 may be a thick region (e.g., 50-1000 microns). The drift region 140 may be provided on an upper surface of the substrate 130. The drift region 140 may be formed of wide bandgap semiconductor materials (e.g., may be an epitaxially grown silicon carbide layer) and may be a lightly-doped n-type (n−) region. The drift region 140 may have, for example, a doping concentration of 1×10¹⁴ to 1×10¹⁷ dopants/cm³ in example embodiments. The drift region 140 may be a thick region, having a vertical height above the substrate 130 of, for example, 3-100 microns. While not shown in FIGS. 2B-2C, in some embodiments an upper portion of the drift region 140 may be more heavily doped (e.g., a doping concentration of 1×10¹⁶ to 2×10¹⁷ dopants/cm³) than the lower portion thereof to provide a current spreading layer in the upper portion of the drift region 140. The thicknesses of the substrate 130 and the drift region 140 are dramatically reduced in FIG. 2B as compared to their actual relative sizes (and the same is true in the other cross-sectional views in the present application) in order to better illustrate the much thinner regions in the upper portion of the semiconductor layer structure 120.

The channel regions 150 are provided on an upper surface of the drift region 140. The channel regions 150 may be formed of wide bandgap semiconductor materials (e.g., epitaxially grown silicon carbide) and may be a moderately doped n-type (n) region. The channel region 150 may have a doping concentration higher than the doping concentration of the lower portion of the drift region 140. For example, a doping concentration of each channel region 150 may be between 1×10¹⁶ to 1×10¹⁷ dopants/cm³. The channel regions 150 may extend below the gate contact regions 182 in the depth direction D (the gate contact regions 182 are discussed below) so that the channel regions 150 are all interconnected (as shown) or may instead extend only as deep as the gate contact regions 182 so that the channel regions 150 are not interconnected.

The source regions 160 are provided on upper surfaces of the channel regions 150. The source regions 160 may be formed of wide bandgap semiconductor materials (e.g., epitaxially grown silicon carbide) and may be heavily-doped n-type (n+) regions. The source regions 160 may have a doping concentration higher than that of the channel regions 150 and may have, for example, a doping concentration of 1×10¹⁸ to 5×10²⁰ dopants/cm³.

In some embodiments, the drift region 140, the channel regions 150 and the source regions 160 may all be formed by one or more epitaxial growth processes using the substrate 130 as a seed layer.

A plurality of longitudinally-extending trenches 152 are formed in an upper surface of the semiconductor layer structure 120 in the active region 102. The trenches extend downwardly through the source region 160 and into the channel region 150 to define a pair of channels 154 between each pair of adjacent trenches 152. The trenches 152 may be formed using one or more etching processes. A plurality of upwardly-extending mesas 162 (i.e., extending upwardly from a bottom surface of the semiconductor layer structure 120 in the depth direction D) are defined between the trenches 152. The source regions 160 are in the upper portions of these mesas 162 so the mesas 162 are typically referred to as “source mesas” 162. The channels 154 are formed in the source mesas 162 underneath the source regions 160. A pair of source mesas 162 form the sidewalls of each trench 152. A larger gate region trench 172 is formed in the gate region 104 in the same etching process that is used to form the trenches 152 in the active region 102.

The gate well region 170 may be formed of wide bandgap semiconductor materials (e.g., silicon carbide) and may be a moderately-doped or heavily-doped p-type (p or p+) region. The gate well region 170 may be formed, for example, by implanting p-type dopants into the regions of the semiconductor layer structure 120 where the gate pad 110 and the gate bus 112 will be formed in subsequent processes to convert selected portions of the n-type channel region 150 into p-type semiconductor material. The gate well 170 is typically formed to cover a slightly larger area than the area covered by the gate pad 110 and the gate bus 112 when the JFET 100 is viewed in plan view. The gate well region 170 may have, for example, a doping concentration of 1×10¹⁹ to 5×10²⁰ dopants/cm³.

A plurality of gate contact regions 182 are formed in the bottoms of the trenches 152 and hence underneath the trenches 152. The gate contact regions 182 may be heavily-doped p-type (p+) silicon carbide regions. The gate contact regions 182 may be formed by implanting p-type dopant ions into the portions of the channel region 150 that are underneath each of the trenches 152 (i.e., by implanting the p-type dopant ions into the bottom of each trench 152). The gate contact regions 182 may be formed in the same ion implantation step that is used to form the gate well region 170, and hence may have the same doping concentration as the gate well region 170 in some cases. Alternatively, the gate contact regions 182 may be formed in a separate ion implantation step so that doping concentrations of the gate well region 170 and the gate contact regions 182 may be set at optimum levels. The gate well region 170 and the gate contact regions 182 may be formed either before or after the trenches 152 and the gate region trench 172 are formed, although typically they are formed after the trenches 152, 172 so that lower ion implantation energies may be used.

A plurality of gate regions 180 are formed in the channel region 150 along the lower sides of each trench 152. The gate regions 180 also extend in the depth direction D along the sidewalls of each gate contact region 182. The gate regions 180 may be formed by ion implantation (e.g., using angled ion implantation steps) into the sidewalls and bottoms of the trenches 152. The gate regions 180 may be moderately-doped p-type (p) regions and may have a doping concentration that is less than the doping concentration of the gate contact regions 182. For example, each gate region 180 may have a doping concentration of 1×10¹⁷ to 1×10¹⁸ dopants/cm³.

The gate pad 110 and the gate bus 112 are provided on the semiconductor layer structure 120 in the gate region trench 172. The gate pad 110 may comprise a metal silicide gate pad region 110S and a metal gate pad 110M that are sequentially stacked on a portion of the gate well region 170. The metal silicide gate pad region 110S directly contacts an upper surface of the gate well region 170 and the metal gate pad 110M is formed on the metal silicide gate pad region 110S opposite the gate well region 170. The gate bus 112 may similarly comprise a metal silicide gate bus region 112S and a metal gate bus 112M that likewise are sequentially stacked on the gate well region 170 so that the metal silicide gate bus region 112S directly contacts the upper surface of the gate well region 170.

The gate pad 110 and the gate bus 112 are spaced apart from one another, as can be seen in both the plan view of FIG. 2A and the cross-sectional view of FIG. 2B. A gate resistor 116 is interposed between the gate pad 110 and the gate bus 112. The gate resistor 116 is implemented as the portion of the gate well region 170 that is in between the gate pad 110 and the gate bus 112. As can best be seen in FIGS. 2A-2B, a gate signal that is applied to the gate bond pad 110 cannot pass to the gate bus 112 through a metalized connection, since no silicide or metal directly connects the gate pad 110 to the gate bus 112. Consequently, the gate signal must flow from the gate pad 110 into the gate well region 170 to pass to the gate bus 112. Since the resistivity of the gate well region 170 is many orders of magnitude higher than the resistivity of the gate pad 110 and gate bus 112, essentially all of the gate current will only flow in the metal 110M/112M and silicide 110S/112S except for in the region of the gate resistor 116 (since no metal or silicide is provided in this region). Thus, the resistance of the gate resistor 116 may be set to a desired value by setting a width thereof (where the width is the distance between the gate pad 110 and the gate bus 112).

As is further shown in FIGS. 2A-2B, a plurality of gate electrodes 114 are formed in the trenches 152 in the active region 102. Each gate electrode 114 may comprise a metal silicide portion 114S and an optional metal portion 114M that is formed on the metal silicide portion 114S. Each gate electrode 114 may extend in the longitudinal direction L and may be formed directly on a respective one of the gate contact regions 182 so that upper surfaces of the gate contact regions 182 directly contact the respective metal silicide regions 114S. The gate contact regions 182 electrically connect the gate electrodes 114 to the gate regions 180. Each unit cell JFET in the active region 102 includes a gate region 180, a gate contact region 182 and a gate electrode 114.

The metal silicide gate pad region 110S, the metal silicide gate bus region 112S and the metal silicide regions 114S of the gate electrodes 114 may be formed of metal silicide (e.g., nickel silicide, tungsten silicide, titanium silicide or molybdenum silicide). The metal gate pad 110M, the metal bus 112M, and the metal regions 114M of the gate electrodes 114 (if provided) may be formed of metal (e.g., aluminum, tungsten, nickel, titanium, ruthenium and/or an alloy thereof).

The power JFET device 100 further includes gate insulating patterns 186 that are provided on the metal gate bus 112M, the metal regions 114M (or metal silicide regions 114S, if the metal regions 114M of the gate electrodes 114 are not provided) and the gate resistor 116. The gate insulating patterns 186 may comprise, for example, one or more dielectric materials such as silicon oxide, silicon nitride, silicon oxynitride or the like.

A source contact 190 is provided on the source regions 160 and the gate insulating patterns 186. The source contact 190 may include one or more layers such as, for example, a diffusion barrier layer and a bulk metal layer. The gate insulating patterns 186 may insulate the gate pad 110 and the gate bus 112 and the gate electrodes 114 from the source contact 190.

A drain pad 192 (e.g., a metal drain pad) may be provided on the bottom side of the power JFET 100 (e.g., on the bottom surface of the substrate 130). The drain pad 192 may be connected to an underlying submount such as a lead frame, a heat sink, a power substrate or the like via soldering, brazing, direct compression or the like.

As the substrate 130, the drift region 140, the channel regions 150 and the source regions 160 all have the same conductivity type (e.g., n-type), each unit cell of the power JFET 100 is normally on, meaning that current will flow between the source contact 190 and the drain contact 192 when no gate signal is applied to the gate pad 110. The JFET 100 is turned off when a sufficient negative gate bias relative to the voltage applied to the source is applied to the gate pad 110 or when the voltage at the JFET source terminal S_{JFET} is brought to a sufficiently high level relative to the gate pad 110.

FIG. 2C is a schematic cross-sectional view taken along line C-C of FIG. 2A. FIG. 2C illustrates the interface between the edge of the active region 102 and the termination region 106 (with the gate bus 112 therebetween).

As shown in FIG. 2C, a plurality of termination structures 108 are formed in the termination region 106. In particular, a plurality of trenches 152T are formed in termination region 106. A plurality of guard rings 184 are formed in the bottoms and lower sidewalls of the trenches 152T. Each guard ring 184 comprises a p-type silicon carbide region that is formed within the n-type silicon carbide channel region 150. Each guard ring 184 includes a central portion 182T that is heavily-doped with p-type dopants and a pair of moderately-doped p-type outer portions 180T. The central portion 182T of each guard ring 184 is formed directly underneath a respective one of the trenches 152T, and the outer portions 180T are formed in the sidewalls of the trenches 152T and on the sidewalls of the central portions 182T. The central portion 182T of each guard ring 184 is formed in the same ion implantation step that is used to form the gate contact regions 182, and the outer portions 180T of each guard ring are formed in the same ion implantation step that is used to form the gate regions 180. Unlike the gate regions 180 and the gate contact regions 182, the guard rings 184 are electrically floating and are only capacitively coupled to each other and to the gate on one side and the drain on the other. The guard rings 184 help reduce electric field crowding effects that may otherwise occur at edges of the active region 102. As shown in FIG. 2C, the source metal 190 is omitted in the termination region 106 and may be replaced with or more insulating layers 186.

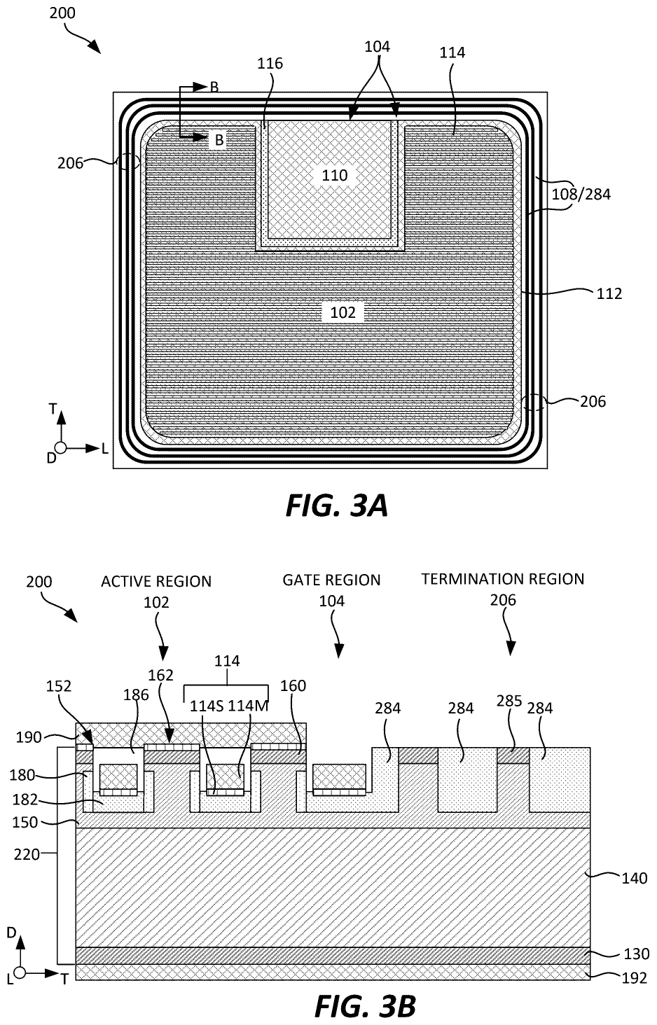

Embodiments of the present invention will now be discussed in greater detail with reference to FIGS. 3A-6B.

FIGS. 3A and 3B are a schematic plan view and cross-sectional view, respectively, of a silicon carbide based gate trench power JFET 200 according to embodiments of the present invention. The active region 102 and gate region 104 of power JFET 200 may be identical to the active region 102 and gate region 104 of power JFET 100, and hence further description of these portions of power JFET 200 will be omitted. As can be seen by comparing FIGS. 2A and 3A, the only difference between JFETs 100 and 200 that is visible in the plan view of FIG. 3A is that power JFET 200 includes three guard rings 284 while power JFET 100 of FIG. 2 only includes two guard rings 184. FIG. 3B is a cross-section taken along line B-B of FIG. 3A that shows the modified termination region 206 included in power JFET 200.

As shown in FIG. 3B, power JFET 200 includes a termination region 206 that has a planar upper surface. Thus, in contrast to JFET 100, no trenches 152T are formed in the termination region 206 of JFET 200. In addition, the semiconductor layer structure 220 of power JFET 200 is not recessed in the termination region 206 so that an upper surface of the termination region 206 may be substantially coplanar with upper surfaces of the source mesas 162 that are provided in the active region 102. As such, the tolerances associated with formation of the trenches 152T that can impact the performance of the guard rings 184 of power JFET 100 are not present in power JFET 200.

A plurality of guard rings 284 are formed in the termination region 206. Each guard ring 284 comprises a p-type silicon carbide region that is formed within the n-type silicon carbide channel region 150. The guard rings 284 may comprise moderately-doped or heavily doped p-type regions, and may have a constant doping profile or a graded doping profile. In example embodiments, the guard rings 284 may have a maximum doping concentration of between 1×10¹⁷ dopants/cm³ and 5×10²¹ dopants/cm³. The guard rings 284 may be electrically floating. The guard rings 284 help reduce electric field crowding effects that may otherwise occur at edges of the active region 102. As shown in FIG. 3B, the source metal 190 does not extend into the termination region 206. One or more insulating layers (not shown) may cover the planar upper surface of the semiconductor layer structure 220 in the termination region 206.

As shown in FIG. 3A, each guard ring 284 may have an annular ring shape when viewed in plan view. The guard rings 284 may, for example, extend to the same depth into the semiconductor layer structure 220 as the gate contact regions 182. As such, the same ion implantation step may be used to form the guard rings 284 and the gate contact regions 182 (this ion implantation step may be performed before the trenches 152 are formed). Alternatively, the guard rings 284 may extend deeper into the semiconductor layer structure 220 than the gate contact regions 182 or shallower into the semiconductor layer structure 220 than the gate contact regions 182 by forming the guard rings 284 and the gate contact regions 182 using different ion implantation steps (or by adding mask material or either the active region 102 or the termination region 206 during a same ion implantation step).

The guard rings 284 included in the termination region 206 of power JFET 200 may be formed using a single ion implantation step. As such, the shape and doping concentrations of the guard rings 284 will only have the tolerances associated with a single ion implantation step, whereas the shape and doping concentrations of the guard rings 184 of JFET 100 have the tolerances associated with multiple ion implantation steps.

The guard rings 284 of power JFET 200 may have a number of advantages compared to the guard rings 184 of power JFET 100. First, the depth that the guard rings 284 extend into the semiconductor layer structure 220 may be set based on a desired electric field shape in the termination region 206 during reverse blocking operation without regard to the depth of any implanted regions in the active region 102 of the device. Second, the doping profile of the guard rings 284 (e.g., the doping concentration as a function of depth) may also be set based on a desired electric field shape in the termination region 206. Thus, the design of the guard rings 284 may be made to optimize shaping of the electric fields in the termination region 206 during reverse blocking operation.

In addition, as noted above, since fewer processing steps are used to form the guard rings 284 as compared to the guard rings 184 of power JFET 100 (e.g., the trench etching step and the additional ion implantation steps used to form guard rings 184 are omitted in the formation of guard rings 284), the number of manufacturing tolerances are reduced, and hence the guard rings 284 may more closely match a desired shape, location, doping concentration, etc. as compared to the guard rings 184 of power JFET 100. This also helps optimize shaping of the electric fields in the termination region 206 during reverse blocking operation. In addition, the p-n junctions that are formed in the sidewalls of the trenches 152T in power JFET 100 are not present in power JFET 200. This can avoid any need to reduce roughness in the trench sidewalls and/or performing a passivation step on the trench sidewalls in the termination region 206 as may be necessary with power JFET 100.

As is also discussed above, the guard rings 284 of power JFET 200 may be formed in a separate ion implantation step or may be formed during an ion implantation step that is used to form the gate contact regions 182 and/or during an ion implantation step that is used to form the gate well region 170. Likewise, the guard rings 284 may be formed before or after the etching step used to form the trenches 152 in the active region 102.

As shown in FIGS. 3A-3B, pursuant to embodiments of the present invention, power JFETs are provided that include a wide bandgap semiconductor layer structure 220 that comprises an active region 102 and a termination region 206. The termination region 206 comprises a plurality of termination structures 108. Moreover, a first major surface (here the upper surface) of the semiconductor layer structure 220 in the active region 102 comprises a plurality of spaced-apart mesas 162 and the first major surface of the semiconductor layer structure 220 in the termination region 206 is a planar surface. The semiconductor layer structure 220 comprises a plurality trenches 152 in the active region 102. Each trench 152 may be a longitudinally-extending trench 152 that is defined between a respective pair of adjacent mesas 162. Moreover, in the embodiment of FIGS. 3A-3B, the upper surface of the semiconductor layer structure 220 in the termination region 206 is coplanar with upper surfaces of the mesas 162.

Referring to FIG. 3B, it can be seen that in the active region 102 the semiconductor layer structure 220 further comprises a drift region 140 having a first conductivity type (here exemplarily shown as n-type) and a plurality of gate regions 180 having a second conductivity type (here shown as p-type). The gate regions 180 are formed in the lower portions of sidewalls of the trenches 152. In addition, a plurality of gate contact regions 182 that also have the second conductivity type are provided in the semiconductor layer structure 220 in the active region 102. The gate contact regions 182 are located underneath the respective trenches 152, and the gate contact regions 182 have a higher second conductivity type dopant concentration than the gate regions 180. As shown, in some case, the gate regions 180 may at least partially cover sidewalls of the gate contact regions 182.

The termination structures 108 comprise a plurality of guard rings 284 that each have the second conductivity type. At least one of the guard rings 284 extends to the first major surface (here the upper surface) of the semiconductor layer structure 220 in the termination region 206. The JFET 200 further comprises a gate pad 110, and the semiconductor layer structure 220 further comprises a gate well region 170 having a second conductivity type underneath the gate pad 110. A bottom surface of the gate well region 170 may be coplanar with bottom surfaces of at least a portion of each termination structure 108.

Still referring to FIGS. 3A-3B, it can be seen that pursuant to further embodiments of the present invention, a power JFET 200 is provided that includes a wide bandgap semiconductor layer structure 220 that comprises an active region 102 and a termination region 206, where a plurality of trenches 152 are provided in an upper surface of the semiconductor layer structure 220 in the active region 102. The semiconductor layer structure 220 comprises a drift region 140 having a first conductivity type (here the first conductivity type is n-type), a plurality of gate contact regions 182 having a second conductivity type (here the second conductivity type is p-type) that are located underneath the respective trenches 152, and at least first and second guard rings 284 that each have the second conductivity type in the termination region 206. Upper surfaces of the first and second guard rings 284 are coplanar with an upper surface of a portion 285 of the semiconductor layer structure that is in between the first and second guard rings 284.

The guard rings 284 extend to the upper surface of the semiconductor layer structure 220 in the termination region 206 so that the upper surfaces of the first and second guard rings 284 form part of the upper surface of the semiconductor layer structure 220 in the termination region 206. The gate contact regions 182 may have a higher second conductivity type dopant concentration than the guard rings 284 in some embodiments. Moreover, the semiconductor layer structure 220 may further comprise a plurality of gate regions 180 having the second conductivity type, where at least some of the gate regions 180 at least partially cover respective sidewalls of the gate contact regions 182. The gate contact regions 182 may have a higher second conductivity type dopant concentration than the gate regions 180. In the active region 102, the semiconductor layer structure 220 further comprises a plurality of source mesas 162, and the trenches 152 are defined between adjacent pairs of source mesas 162. In the embodiment of FIGS. 3A-3B, upper surfaces of the first and second guard rings 284 are coplanar with upper surfaces of the source mesas 162.

As can also be seen from FIGS. 3A-3B, pursuant to still further embodiments of the present invention, a power JFET 200 is provided that comprises a wide bandgap semiconductor layer structure 220 that comprises a drift region 140 having a first conductivity type (here, n-type). The semiconductor layer structure 220 includes an active region 102 having a plurality of source mesas 162 and a plurality of trenches 152 that are defined between respective adjacent pairs of the source mesas 162, as well as a termination region 206 that comprises a plurality of guard rings 284 that have a second conductivity type (here, p-type), where each guard ring 284 has a planar upper surface and outer portions of each guard ring 284 and a central portion of each guard ring 284 have a same doping concentration as a function of depth into the semiconductor layer structure 220

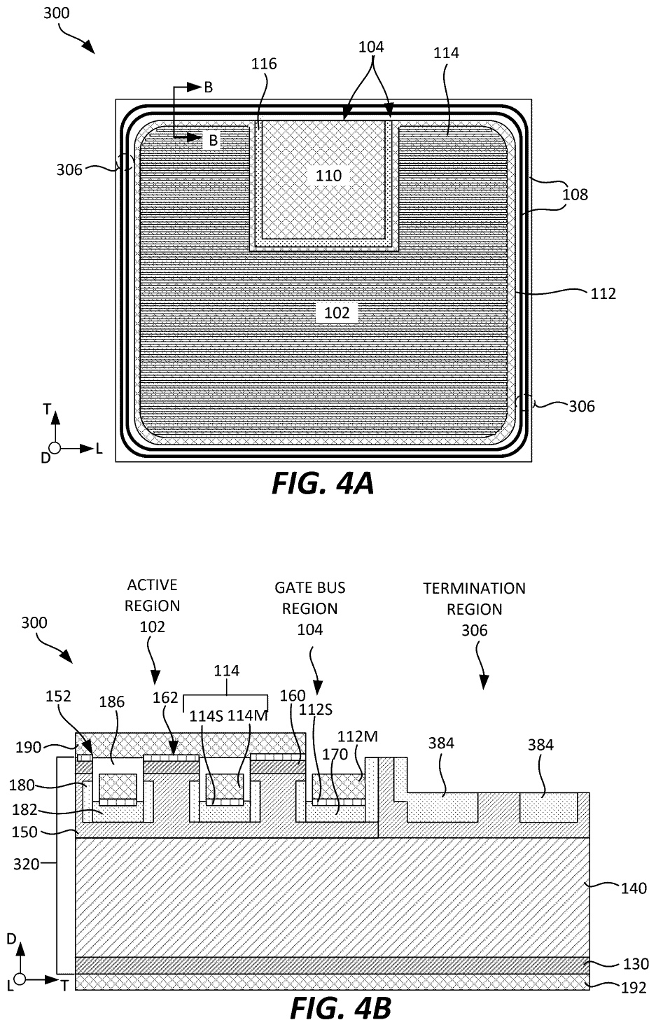

FIGS. 4A and 4B are a schematic plan view and cross-sectional view, respectively, of a silicon carbide based gate trench power JFET 300 according to further embodiments of the present invention, where FIG. 4B is a cross-section taken along line B-B of FIG. 4A. The active region 102 and gate region 104 of power JFET 300 may be identical to the active region 102 and gate region 104 of power JFET 100, and hence further description of these portions of power JFET 300 will be omitted. As can be seen by comparing FIGS. 2A and 4A, power JFETs 100 and 200 may appear identical in plan view.

Referring to FIG. 4B, power JFET 300 includes a termination region 306 that is similar to the termination region 206 of power JFET 200, except that the termination region 306 is recessed to be below a plane defined by the upper surfaces of the source mesas 162. The termination region 306 thus may have a planar upper surface, but that upper surface is recessed to be below a level of the upper surface of power JFET 300 in the active region 102. Otherwise, power JFET 300 may be identical to power JFET 200 of FIGS. 3A-3B. Recessing the upper surface of the semiconductor layer structure 300 in the termination region 306 of power JFET 300 may allow the guard rings 384 to be formed using lower ion implantation energies. In some embodiments, the guard rings 384 and the gate contact regions 182 may be formed in a same ion implantation step that is performed before the trenches 152 are formed in the active region 102. The termination region 306 may be recessed so that the upper surface of the termination region 306 is coplanar with the bottoms of the trenches 152 in some embodiments. In other embodiments, the termination region 306 may be recessed so that the upper surface of the termination region 306 is below a plane defined by the bottoms of the trenches 152, while in still other embodiments the termination region 306 may be recessed so that the upper surface of the termination region 306 is above a plane defined by the bottoms of the trenches 152 but below a plane defined by the upper surfaces of the source mesas 162.

As shown in FIGS. 4A-4B, pursuant to embodiments of the present invention, a power JFET 300 is provided that comprises an active region 102 and a termination region 306 that at least partially surrounds the active region 102. The JFET 300 comprises a semiconductor layer structure 320 that comprises a wide bandgap semiconductor material, the semiconductor layer structure 320 comprising a drift region 340 having a first conductivity type (here shown as n-type), a plurality of source mesas 162 on the drift region 140 in the active region 102, and a plurality of trenches 152 that are defined between respective adjacent pairs of the source mesas 162. The semiconductor layer structure 320 has a planar upper surface in the termination region 306 that is not coplanar with a plane defined by upper surfaces of the source mesas 162.

The planar upper surface of the semiconductor layer structure 320 in the termination region 306 is recessed below upper surfaces of the source mesas 162. In the depicted embodiment, the planar upper surface of the semiconductor layer structure 320 in the termination region 306 is substantially coplanar with bottom surfaces of the trenches 152. The semiconductor layer structure 320 further comprises a plurality of gate regions 180 having a second conductivity type (here, p-type) that are formed in lower portions of the sidewalls of the trenches 152. The semiconductor layer structure further comprises a plurality of gate contact regions 182 having the second conductivity type that are located underneath the respective trenches 152, wherein the gate contact regions 182 have a higher second conductivity type dopant concentration than do the gate regions 180, and the gate regions 180 at least partially cover sidewalls of the gate contact regions 182.

The termination region 306 comprises a plurality of guard rings 384 that have the second conductivity type, and at least one of the guard rings 384 extends to the planar upper surface of the semiconductor layer structure 320 in the termination region 306. The JFET 300 further comprising a gate pad 110, and the semiconductor layer structure 320 further comprises a gate well region 170 having the second conductivity type underneath the gate pad 110. A bottom surface of the gate well region 170 is coplanar with bottom surfaces of at least a portion of each guard ring 384 (or other termination structure).

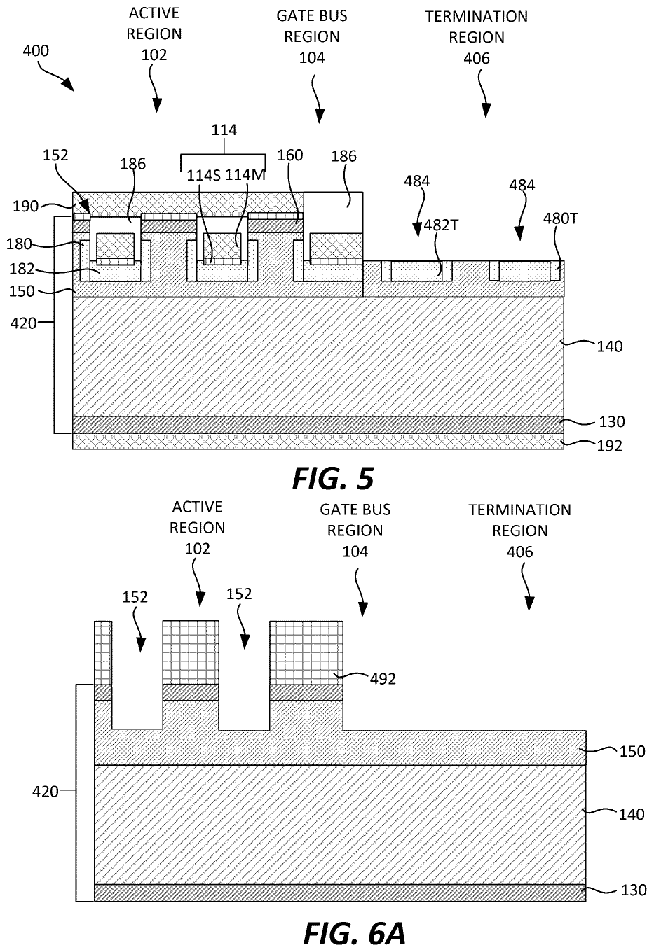

FIG. 5 is a schematic cross-sectional view of a power JFET 400 according to still further embodiments of the present invention. The power JFET 400 is similar to the power JFET 100 of FIGS. 2A-2C, except that the termination region 406 of power JFET 400 has a planar upper surface that is recessed to be substantially coplanar with a plane defined by the bottoms of the trenches 152 in the active region 102. It will be appreciated that the cross-section of FIG. 5 corresponds to the cross-section of FIG. 2C and illustrates the differences between power JFET 100 and power JFET 400. The active region 102 and gate region 104 of power JFET 400 may be identical to the active region 102 and gate region 104 of power JFET 100, and hence further description of these portions of power JFET 400 will be omitted.

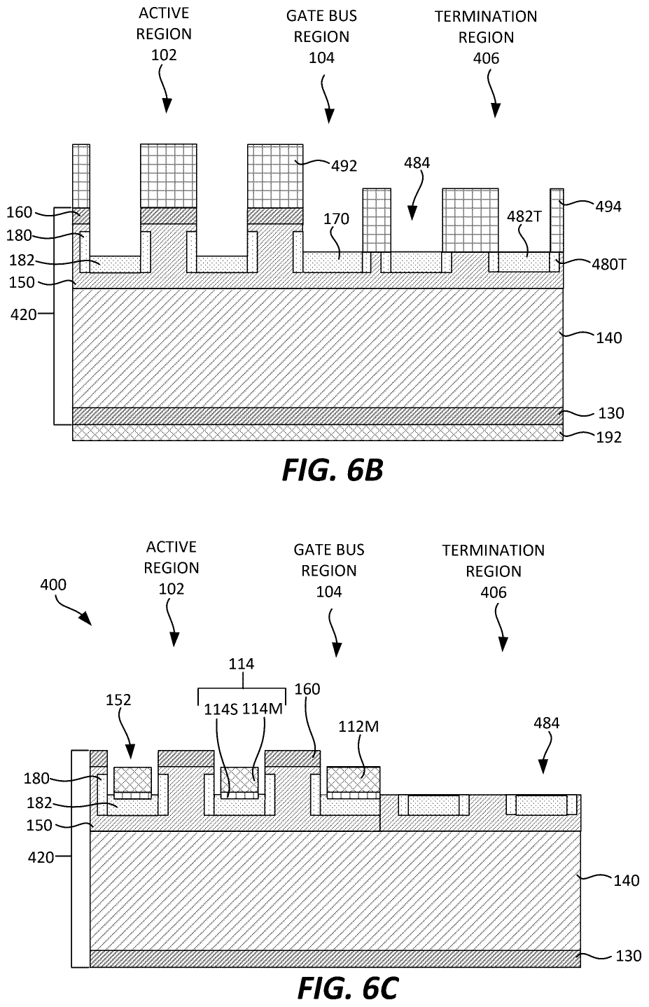

As can be seen by comparing FIGS. 2C and 5, power JFET 400 differs from power JFET 100 in that power JFET 400 does not include mesas in the termination region 406 thereof. Instead, the entire upper surface of the termination region 406 is recessed (via an etching step). A plurality of guard rings 484 are formed in the termination region 406 of power JFET 400. As shown, each guard ring 484 comprises a p-type silicon carbide region that is formed within the n-type silicon carbide channel region 150. Each guard ring 484 includes a central portion 482T that is heavily-doped with p-type dopants and a pair of moderately-doped p-type outer portions 480T. The central portions 482T of each guard ring 484 may formed during an ion implantation step that is performed to form the gate contact regions 182, and the outer portions 480T of each guard ring 484 may formed during angled ion implantation steps that are performed to form the gate regions 180. As will be discussed below with reference to FIGS. 6A-6C, an additional mask may be formed in the termination region 406 prior to these ion implantation steps. The power JFET 400 may use relatively low implant energies in forming the guard rings 484, and may not require any extra ion implantation steps to form the guard rings 484. In addition, the termination region 406 of power JFET 400 may have a planar upper surface and hence may have the above-discussed advantages that such a planar surface provides in terms of reduced tolerance stacking and the absence of any p-n junction in trench sidewalls in the termination region.

FIGS. 6A-6C are schematic cross-sectional views illustrating a method of fabricating the power JFET 400 of FIG. 5.

As shown in FIG. 6A, an n-type drift region 140 may be formed in an n-type semiconductor substrate 130, and an n-type channel region 150 may be formed on the n-type drift region 140 by epitaxial growth. The n-type channel region 150 may also be formed by epitaxial growth, and may be doped during growth and/or via ion implantation. An n-type source layer may be formed in the upper portion of the n-type channel region 150, where the source layer is more heavily doped n-type than the channel region. The substrate 130, drift region 140, channel region 150 and source layer may form a semiconductor layer structure 420.

Still referring to FIG. 6A, next, a mask layer may be formed on an upper surface of the semiconductor layer structure 420, and the mask layer may be patterned to provide a first mask pattern 492 that exposes the upper surface of the semiconductor layer structure 420 in the termination region 406 and selected portions of the semiconductor layer structure 420 in the active region 102 and gate region 104. An etching process may then be performed using the first mask pattern 492 as an etching mask to form trenches 152 in the upper surface of the semiconductor layer structure 420 in the active region 102 and the gate region, and to etch away the upper surface of the semiconductor layer structure 420 in the termination region 406. As shown, after this etching step is completed the upper surface of the semiconductor layer structure 420 in the termination region 406 may be coplanar with a plane defined by the bottoms of the trenches 152 in the active region 102.

Referring to FIG. 6B, a second mask layer is formed on the semiconductor layer structure 420 and this mask layer is patterned to provide a second mask pattern 494 that covers selected portions of the termination region 406. An ion implantation process is then performed using the first and second mask patterns 492, 494 as ion implantation masks, to form the gate contact regions 182 in the active region 102, to form the gate well region 170 in the gate region 104, and to form the central portions 482T of the respective guard rings 484 in the termination region. Next, angled ion implantation processes are performed to form the gate regions 180 in the active region 102 and to form the outer portions 480T of the guard rings 484 in the termination region 406.

Referring to FIG. 6C, a mask (not shown) is formed leaving a plurality of openings and metal is then deposited into the openings in the mask to form the gate pad 110, the gate bus 112 and the gate electrodes 114. Conventional processing may then be performed to complete the JFET 400 of FIG. 5.

While the semiconductor devices discussed above are n-type devices, it will be appreciated that in p-type devices the conductivity of each n-type and p-type region would be reversed. Thus, it will be appreciated that while n-type JFETs are discussed above by way of example, any of the JFETs disclosed herein may alternatively be implemented as a p-type JFET. Moreover, while the above-described power semiconductor devices and the other devices described herein are shown as being silicon carbide-based semiconductor devices, it will be appreciated that embodiments of the present invention are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A junction field effect transistor (“JFET”), comprising:
a wide bandgap semiconductor layer structure comprising an active region and a termination region, the termination region comprising a plurality of termination structures, wherein a first major surface of the semiconductor layer structure in the active region comprises a plurality of spaced-apart mesas and the first major surface of the semiconductor layer structure in the termination region is a planar surface.

2. The JFET of claim 1, wherein the semiconductor layer structure further comprises a plurality trenches in the active region.

3. (canceled)

4. The JFET of claim 1, wherein the first major surface of the semiconductor layer structure in the termination region is coplanar with upper surfaces of the mesas.

5. The JFET of claim 2, wherein the first major surface of the semiconductor layer structure in the termination region is substantially coplanar with bottom surfaces of the trenches.

6. The JFET of claim 1, wherein the first major surface of the semiconductor layer structure in the termination region is closer to a second major surface of the semiconductor layer structure that is opposite the first major surface of the semiconductor layer structure than are upper surfaces of the mesas.

7. The JFET of claim 6, wherein the first major surface of the semiconductor layer structure in the termination region is further from the second major surface of the semiconductor layer structure than are bottom surfaces of the trenches.

8. The JFET of claim 2, wherein in the active region the semiconductor layer structure further comprises a drift region having a first conductivity type, a channel region having the first conductivity type, and a plurality of gate regions having a second conductivity type.

9-11. (canceled)

12. The JFET of claim 8, wherein the plurality of termination structures comprises a plurality of guard rings that have the second conductivity type, and at least one of the guard rings extends to the first major surface of the semiconductor layer structure in the termination region.

13. The JFET of claim 12, wherein each guard ring comprises a central region and first and second outer regions that at least partially cover sidewalls of the central region, where the central region has a higher second conductivity type dopant concentration than the first and second outer regions.

14. (canceled)

15. The JFET of claim 13, the JFET further comprising a gate pad, and the semiconductor layer structure further comprises a gate well region having a second conductivity type region underneath the gate pad, wherein bottom surfaces of central regions of the guard rings are coplanar with the bottom surface of the gate well region.

16. The JFET of claim 8, the JFET further comprising a gate pad, and the semiconductor layer structure further comprises a gate well region having a second conductivity type region underneath the gate pad, where a bottom surface of the gate well region is coplanar with a bottom surface of at least a portion of each termination structure.

17. (canceled)

18. A junction field effect transistor (“JFET”), comprising:
a wide bandgap semiconductor layer structure that comprises an active region and a termination region, where a plurality of trenches are provided in an upper surface of the semiconductor layer structure in the active region,
wherein the semiconductor layer structure comprises a drift region having a first conductivity type and a plurality of gate contact regions having a second conductivity type that are located underneath the respective trenches in the active region, and first and second guard rings having the second conductivity type in the termination region,
wherein upper surfaces of the first and second guard rings are coplanar with an upper surface of a portion of the semiconductor layer structure that is in between the first and second guard rings.

19. The JFET of claim 18, wherein upper surfaces of the first and second guard rings form part of the upper surface of the semiconductor layer structure in the termination region.

20. The JFET of claim 19, wherein the gate contact regions have a higher second conductivity type dopant concentration than the first and second guard rings.

21. The JFET of claim 20, wherein the semiconductor layer structure further comprises a plurality of gate regions having the second conductivity type, where at least some of the gate regions at least partially cover respective sidewalls of the gate contact regions, wherein the gate contact regions have a higher second conductivity type dopant concentration than the gate regions.

22. The JFET of claim 21, wherein, in the active region, the semiconductor layer structure comprises a plurality of source mesas, and the trenches are defined between adjacent pairs of source mesas.

23. The JFET of claim 22, wherein the upper surfaces of the first and second guard rings are coplanar with upper surfaces of the source mesas.

24. The JFET of claim 22, wherein the upper surfaces of the first and second guard rings are substantially coplanar with bottom surfaces of the trenches.

25. (canceled)

26. The JFET of claim 18, wherein the first guard ring comprises a central region and first and second outer regions that at least partially cover sidewalls of the central region, where the central region has a higher second conductivity type dopant concentration than the first and second outer regions.

27-28. (canceled)

29. A junction field effect transistor (“JFET”) that comprises an active region and a termination region that at least partially surrounds the active region, the JFET comprising:
a semiconductor layer structure that comprises a wide bandgap semiconductor material, the semiconductor layer structure comprising a drift region having a first conductivity type, a plurality of source mesas on the drift region in the active region, and a plurality of trenches that are defined between respective adjacent pairs of the source mesas,
wherein the semiconductor layer structure has a planar upper surface in the termination region that is not coplanar with a plane defined by upper surfaces of the source mesas.

30. The JFET of claim 29, wherein the planar upper surface of the semiconductor layer structure in the termination region is recessed below upper surfaces of the source mesas.

31-34. (canceled)

35. The JFET of claim 30, wherein the termination region comprises a plurality of guard rings that have the second conductivity type, and at least one of the guard rings extends to the planar upper surface of the semiconductor layer structure in the termination region.

36. The JFET of claim 35, wherein each guard ring comprises a central region and first and second outer regions that at least partially cover sidewalls of the central region, where the central region has a higher second conductivity type dopant concentration than the first and second outer regions.

37. The JFET of claim 36, wherein a first height of the gate regions in a depth direction that is perpendicular to a lower surface of the semiconductor layer structure is greater than second heights of the first and second outer regions of the guard rings in the depth direction.

38-62. (canceled)
